(19) United States
(12) Patent Application Publication
(10) Pub. No.: US 2022/0066266 A1
(43) Pub. Date: Mar. 3, 2022

(54) ILLUMINATING DEVICE AND DISPLAY APPARATUS

(71) Applicant: Japan Display Inc., Tokyo (JP)

(72) Inventors: Takashi OTA, Tokyo (JP); Masafumi OKADA, Tokyo (JP); Toshihiro YAJIMA, Tokyo (JP)

(73) Assignee: Japan Display Inc., Tokyo (JP)

(21) Appl. No.: 17/454,642

(22) Filed: Nov. 12, 2021

Related U.S. Application Data
(63) Continuation of application No. PCT/JP2020/015570, filed on Apr. 6, 2020.

(30) Foreign Application Priority Data
May 17, 2019 (JP) 2019-093770

(51) Int. Cl. G02F 1/13357; G02F 1/1335

(52) U.S. Cl. CPC G02F 1/133603; G02F 1/133606; G02F 1/133609; G02F 1/133612

(57) ABSTRACT

According to one embodiment, an illuminating device includes a wiring substrate, light emitting elements, a wavelength conversion element, and a protrusion. A main surface of the wiring substrate is divided into segment areas. N light emitting elements are disposed in each of the segment areas. N is greater than 1. The light emitting elements are driven independently in units of the segment areas. The protrusion protrudes from the wiring substrate toward the wavelength conversion element between two segment areas adjacent to each other.

### CROSS-REFERENCE TO RELATED APPLICATIONS

This application is a Continuation Application of PCT Application No. PCT/JP2020/015570, filed Apr. 6, 2020 and based upon and claiming the benefit of priority from Japanese Patent Application No. 2019-093770, filed May 17, 2019, the entire contents of all of which are incorporated herein by reference.

### FIELD

Embodiments described herein relate generally to an illuminating device and a display apparatus.

### BACKGROUND

Generally, various illuminating devices are known. For example, an illuminating device which illuminates a liquid crystal display panel as an illuminating device is known. The illuminating device comprises a plurality of light-emitting diodes (LEDs) arranged in two dimensions.

When the LEDs are turned on, the luminance level undesirably varies in the light emitting area of the illuminating devices in some cases. For example, this may cause a situation where the luminous spots of the LEDs are viewed as a dot pattern by the user.

On the other hand, if a means for diffusing light emitted from the LEDs is added to the illuminating device, the occurrence of undesired variations in the luminance level in the light emitting area can be suppressed. However, a halo effect occurs in the light emitting area in some cases. When a halo effect occurs, light emitted from the LEDs are undesirably diffused, and the luminance levels of areas adjacent to the LEDs are undesirably increased. Consequently, the contrast ratio is reduced.

### BRIEF DESCRIPTION OF THE DRAWINGS

FIG. 1 is a block diagram showing a display apparatus according to one embodiment.

FIG. 2 is an exploded perspective view showing an illuminating device shown in FIG. 1.

FIG. 3 is a plan view showing a part of an illuminating device according to Example 1 of the embodiment.

FIG. 4 is a cross-sectional view showing the illuminating device along line IV-IV of FIG. 3.

FIG. 5 is a cross-sectional view showing a light emitting element along line V-V of FIG. 3.

FIG. 6 is a plan view showing a part of an illuminating device according to Example 2 of the embodiment.

FIG. 7 is a cross-sectional view showing the illuminating device along line VII-VII of FIG. 6.

FIG. 8 is a graph showing relative luminance in each of Examples 1 and 2.

FIG. 9 is a graph showing relative luminance in each of Examples 2, 3 and 4.

FIG. 10 is a plan view showing an illuminating device according to Modification 1 of the embodiment.

FIG. 11 is a cross-sectional view showing an illuminating device according to Modification 2 of the embodiment.

FIG. 12 is a cross-sectional view showing an illuminating device according to Modification 3 of the embodiment.

FIG. 13 is a cross-sectional view showing an illuminating device according to Modification 4 of the embodiment.

FIG. 14 is an exploded perspective view showing an illuminating device according to Modification 5 of the embodiment.

### DETAILED DESCRIPTION

In general, according to one embodiment, there is provided an illuminating device comprising a wiring substrate, a plurality of light emitting elements disposed on a main surface of the wiring substrate, a wavelength conversion element irradiated with light emitted from the light emitting elements, and a protrusion. The main surface of the wiring substrate is divided into a plurality of segment areas. N light emitting elements are disposed in each of the segment areas. N is greater than 1. The light emitting elements are driven independently in units of the segment areas. The protrusion protrudes from the wiring substrate toward the wavelength conversion element between two segment areas adjacent to each other.

According to another embodiment, there is provided a display apparatus comprising a display panel, and an illuminating device illuminating the display panel. The illuminating device comprises a wiring substrate, a plurality of light emitting elements disposed on a main surface of the wiring substrate, a wavelength conversion element irradiated with light emitted from the light emitting elements, and a protrusion. The main surface of the wiring substrate is divided into a plurality of segment areas. N light emitting elements are disposed in each of the segment areas. N is greater than 1. The light emitting elements are driven independently in units of the segment areas. The protrusion protrudes from the wiring substrate toward the wavelength conversion element between two segment areas adjacent to each other.

One embodiment of the present invention will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, the same elements as those described in connection with preceding drawings are denoted by the same reference numbers, and detailed description thereof is omitted where appropriate.

FIG. 1 is a block diagram showing a display apparatus DSP according to one embodiment. FIG. 1 shows a three dimensional space defined by a first direction X, a second direction Y perpendicular to the first direction X, and a third direction Z perpendicular to each of the first direction X and the second direction Y. It should be noted that the first direction X and the second direction Y are orthogonal to each other but may cross each other at an angle other than 90°. In addition, the third direction Z is defined as above and the opposite direction to the third direction Z is defined as below in the present embodiment. When described as the second member above the first member or the second member below the first member, the second member may be in contact with the first member or may be apart from the first member. Furthermore, when an observation position from which the display apparatus DSP is observed is located at the pointed end side of the arrow of the third direction Z, and viewing from this observation position toward an X-Y plane defined by the first direction X and the second direction Y is referred to as planar view.

As shown in FIG. 1, the display apparatus DSP comprises a display panel PNL and an illuminating device IL. In the present embodiment, the display panel PNL is a generally known transmissive or transreflective liquid crystal display panel. However, the display panel PNL is not limited to a liquid crystal display panel but is a display panel which requires a light source separately such as a micro electro-mechanical system (MEMS) display panel.

The illuminating device IL is opposed to the display panel PNL in the third direction Z. The illuminating device IL is configured to emit light toward the display panel PNL and illuminate the display panel PNL. In the present embodiment, the illuminating device IL functions as a backlight unit. The display panel PNL is configured to display an image by selectively transmitting light from the illuminating device IL.

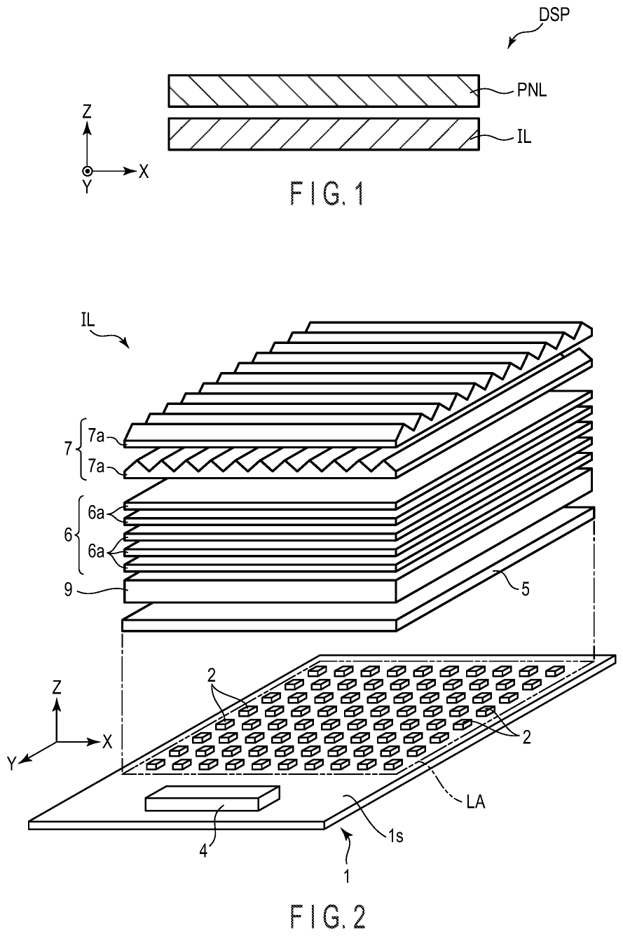

FIG. 2 is an exploded perspective view showing the illuminating device IL shown in FIG. 1.

As shown in FIG. 2, the illuminating device IL comprises a wiring substrate 1, a plurality of light emitting elements 2, a driver 4, a protective layer 5, a light diffuser 6, a luminance improver 7 and a wavelength converter 9. The wiring substrate 1, the light emitting elements 2, the protective layer 5, the wavelength converter 9, the light diffuser 6 and the luminance improver 7 are stacked in the third direction Z without any space.

The wiring substrate 1 is a printed substrate. In the present embodiment, the wiring substrate 1 is composed of a flexible printed circuit (FPC). However, the wiring substrate 1 is not limited to a flexible printed circuit but may be composed of a printed circuit board (PCB). The wiring substrate 1 has a light emitting area LA. The light emitting area LA is opposed to at least the display area of the display panel (PNL).

The light emitting elements 2 are mounted on a main surface 1s of the wiring substrate 1. In the embodiment, the light emitting elements 2 are mini-light-emitting diodes (mini-LEDs). The driver 4 is mounted on the main surface 1s outside the light emitting area LA. The driver 4 is configured to drive the light emitting elements 2 via the wiring substrate 1.

The light emitting elements 2 output a specific wavelength of light, and the wavelength converter 9 converts and outputs the wavelength of light emitted from the light emitting elements 2. The wavelength converter 9 as a wavelength conversion element is located between the protective layer 5 and the light diffuser 6. The wavelength converter 9 includes, for example, quantum dots as a light emitting material, and absorbs incident light such as light emitted from the light emitting elements 2 and emits light having a longer wavelength than the wavelength of the absorbed light. For example, the light emitting elements 2 are blue LEDs having a main emission peak wavelength of less than or equal to 500 nm, and the wavelength converter 9 is a phosphor which absorbs light emitted from the light emitting elements 2 and emits light having a wavelength of greater than or equal to 500 nm.

The light diffuser 6 is located above the light emitting elements 2. The light diffuser 6 is configured to diffuse and emit light emitted from the light emitting elements 2. In the present embodiment, the light diffuser 6 is a light diffusion film composed of five light diffusion sheets 6a stacked on top of each other. However, the light diffuser 6 (light diffusion film) may be composed of one light diffusion sheet 6a or may be composed of four or less light diffusion sheets 6a or six or more light diffusion sheets 6a stacked on top of each other.

The protective layer 5 is located between the main surface 1s and the wavelength converter 9.

The luminance improver 7 is located above the light diffuser 6. The luminance improver 7 is configured to focus and emit light from the light diffuser 6 in the third direction Z. In the present embodiment, the luminance improver 7 is composed of two orthogonally-arranged refraction prism sheets 7a. However, the luminance improver 7 may be composed of total reflection prism sheets instead of the refraction prism sheets 7a. Total reflection prism sheets have the characteristics that they have a simple configuration and excellent light use efficiency and vertical focusing properties.

### Example 1

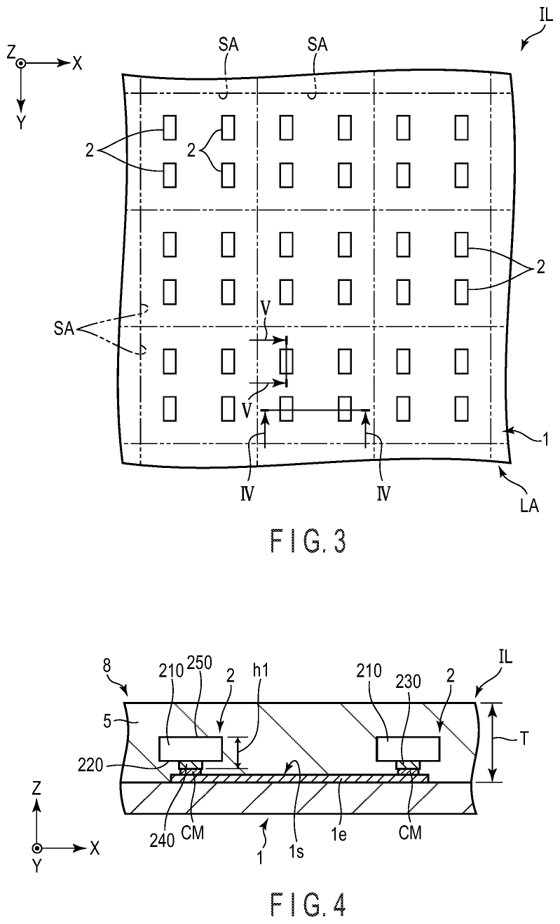

Next, the illuminating device IL according to Example 1 of the present embodiment will be described. FIG. 3 is a plan view showing a part of the illuminating device IL according to Example 1. The wiring substrate 1 and the light emitting elements 2 of the illuminating device IL are illustrated in FIG. 3.

As shown in FIG. 3, the light emitting area LA has a plurality of segment areas SA. In other words, the light emitting area LA of the main surface 1s is divided into the segment areas SA. In Example 1, the segment areas SA are arranged in a matrix in the first direction X and the second direction Y. In one example, as the segment areas SA, 30 segment areas are arranged in the first direction X and 32 segment areas are arranged in the second direction Y. However, the segment areas SA may not be arranged in a matrix but only need to be located adjacent to each other.

In addition, the segment areas SA have a square shape whose sides are 2 mm. However, the size and shape of the segment areas SA are not limited to the above example.

The light emitting elements 2 are arranged in a matrix in the first direction X and the second direction Y. However, the light emitting elements 2 may not be arranged in a matrix but may be arranged in a predetermined pattern.

In the illuminating device IL, n (n>1) light emitting elements 2 are disposed in each of the segment areas SA. In Example 1, four light emitting elements 2 are disposed in each segment area SA. However, two, three or five or more light emitting elements 2 may be disposed in each segment areas SA.

The four light emitting elements 2 disposed in each segment area SA are connected in series. The light emitting elements 2 disposed in different segment areas SA are electrically insulated from each other. The driver 4 is configured to drive the light emitting elements 2 independently in units of segment areas SA via the wiring substrate 1. For example, the driver 4 can drive the light emitting elements 2 by a technique called local dimming. Accordingly, the contrast ratio can be further increased.

In planar view, the light emitting elements 2 have a rectangular shape. However, the shape of the light emitting elements 2 may be a shape other than a rectangular shape such as a square shape. In planar view, the length of one side of the light emitting element 2 which is a mini-LED is, for example, greater than 100 μm but less than 300 μm. The length of one side of the light emitting element 2 which is a mini-LED may be greater than 100 μm but less than or equal to 200 μm.

It should be noted that the light emitting element 2 may be a micro-LED whose longest side length is less than or equal to 100 μm as an LED smaller than a mini-LED. Alternatively, the light emitting element 2 may be an LED whose longest side length is less than or equal to 1 mm. Alternatively, the light emitting element 2 may be an LED whose longest side length is greater than or equal to 1000 μm as a general LED larger than a mini-LED. The length of one side of the light emitting element 2 which is a general LED is, for example, greater than or equal to 300 μm but less than or equal to 350 μm.

FIG. 4 is a cross-sectional view showing the illuminating device IL along line IV-IV of FIG. 3. The wiring substrate 1, the light emitting elements 2 and the protective layer 5 of the illuminating device IL are illustrated in FIG. 4.

As shown in FIG. 4, the light emitting elements 2 are mounted on the wiring substrate 1 by a method called flip-chip bonding. In the flip-chip bonding, a bear chip which is cut from a board but is not packaged is connected to the wiring substrate 1 by a conductive material CM such as solder, gold or an anisotropic conductive film. A part 210 in the drawing is a light transmissive substrate as a base, and each light emitting element 2 has pads 230 and 240 on a surface (bottom surface 220) of the substrate 210 which is opposed to the wiring substrate 1. As will be described later, each light emitting element 2 has two pads 230 and 240. One of the pads 230 and 240 is connected to the anode of the light-emitting diode from the bottom surface 220 side, and the other is connected to the cathode from the bottom surface 220 side.

A connection electrode 1e is formed of copper foil or the like on the wiring substrate 1. The connection electrode 1e forms a part of the main surface 1s. The substrate 210 has a surface (top surface) 250 opposed to the bottom surface 220, and the surface 250 of the light emitting element 2 is heated and pressed in the flip-chip bonding. By heated and pressed from the surface 250, the pads 230 and 240 are connected to the connection electrode 1e via the conductive material CM such as solder, gold or an anisotropic conductive film.

Since the surface 250 of the substrate 210 is heated and pressed, a phosphor or the like cannot be disposed on the surface 250. Therefore, after the light emitting elements 2 are mounted on the wiring substrate 1, the wavelength converter 9 is formed separately from the light emitting elements 2. In addition, unlike wire bonding, no connection portion is formed on the surface 250 of the substrate 210 so that a wiring line can be shortened. In the wire bonding, since a wire is drawn to connect from the surface to the wiring substrate, the length is greater than the thickness of the substrate 210. However, in the flip-chip bonding, the length of a wiring line is the distance from the bottom surface 220 of the substrate 210 to the wiring substrate 1.

As shown in FIG. 4, the protective layer 5 is disposed on the main surface 1s and the light emitting elements 2, and is in contact with the main surface 1s and the light emitting elements 2. The protective layer 5 is configured to protect the light emitting elements 2. The protective layer 5 is located at least in the light emitting area (LA). The wiring substrate 1, the light emitting elements 2 and the protective layer 5 constitute a light source 8 together with the above-described driver (4).

In Example 1, the protective layer 5 is configured as a light transmissive layer which transmits the wavelength of light emitted from the light emitting elements 2. The protective layer 5 is formed of, for example, silicon resin. The protective layer 5 is configured to transmit light emitted from the light emitting elements 2 without converting its wavelength into a different wavelength. In this case, the wavelength of light transmitted through the protective layer 5 is converted into a different wavelength in the wavelength converter 9.

However, the configuration of the protective layer 5 is not limited to the above example.

For example, the protective layer 5 may be configured as a wavelength conversion layer which converts the wavelength of light emitted from the light emitting elements 2. The protective layer 5 includes, for example, quantum dots as a light emitting material, and can absorb light emitted from the light emitting elements 2 and emit light having a longer wavelength than the wavelength of the absorbed light. In this case also, the light source 8 can emit light having a desired color phase. In one example, the light emitting elements 2 emit blue and the quantum dots of the protective layer 5 and the wavelength converter emit yellow which is a complementary color to blue so that the illuminating device IL can emit white light which is combined light of blue light and yellow light which is wavelength converted by the protective layer 5 and the wavelength converter 9.

Alternatively, the protective layer 5 may be configured as a photosynthetic layer in which a plurality of phosphors are dispersed in a light transmissive layer. The light transmissive layer is configured to transmit the wavelength of light emitted from the light emitting elements 2, and is formed of, for example, silicon resin. The phosphors absorb light emitted from the light emitting elements 2, and emit light having a different wavelength. In this case also, the light source 8 can emit light having a desired color phase. For example, when the light emitting elements 2 emit blue light and the phosphors of the protective layer 5 and the quantum dots of the wavelength converter 9 emit yellow light, the illuminating device IL can emit white combined light.

In Example 1, a height h1 of the light emitting elements 2 is 80 μm, and a thickness T of the protective layer 5 is 0.3 mm. The illuminating device IL of Example 1 is configured as described above.

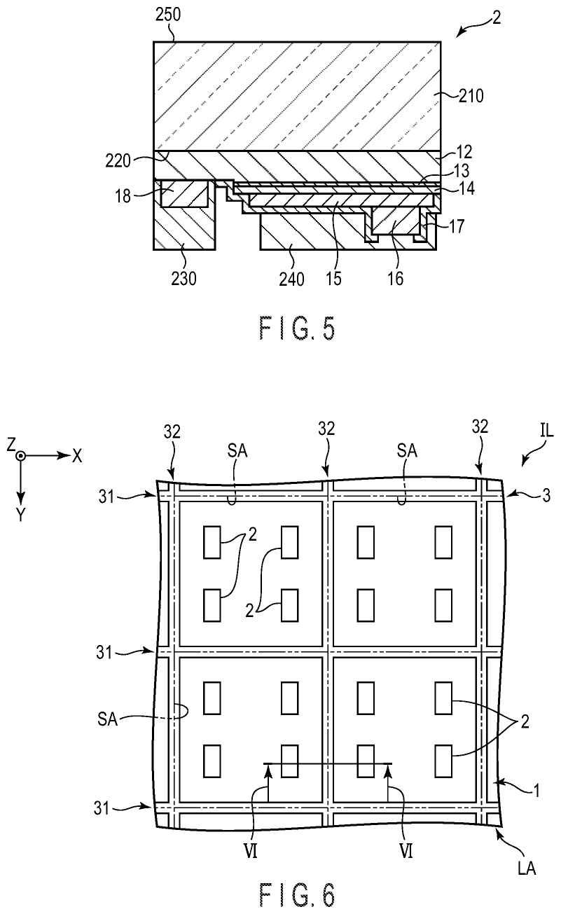

An example of the structure of the light emitting elements 2 will be described blow. FIG. 5 is a cross-sectional view showing the light emitting element 2 along line V-V of FIG. 3.

As shown in FIG. 5, the light emitting element 2 is a flip-chip light-emitting diode element. The light emitting element 2 comprises the insulating transparent substrate 210. The substrate 210 is, for example, a sapphire substrate. A crystalline layer (semiconductor layer) in which an n-type semiconductor layer 12, an active layer (light-emitting layer) 13 and a p-type semiconductor layer 14 are stacked in order is formed on the bottom surface 220 of the substrate 210. In the crystalline layer (semiconductor layer), an area including p-type impurities is the p-type semiconductor layer 14, and an area including n-type impurities is the n-type semiconductor layer 12. The material of the crystalline layer (semiconductor layer) is not limited in particular, but the crystalline layer (semiconductor layer) may contain gallium nitride (GaN) or gallium arsenide (GaAs).

A light reflective film 15 is formed of a conductive material, and is electrically connected to the p-type semiconductor layer 14. A p electrode 16 is electrically connected to the light reflective film 15. An n electrode 18 is electrically connected to the n-type semiconductor layer 12. The pad 230 covers the n electrode 18, and is electrically connected to the n electrode 18. A protective layer 17 covers the n-type semiconductor layer 12, the active layer 13, the p-type semiconductor layer 14 and the light reflective film 15, and covers a part of the p electrode 16. The pad 240 covers the p electrode 16, and is electrically connected to the p electrode 16.

When the local dimming is performed, it is desirable that one segment SA should emit light uniformly. It is necessary that the amount of light should be constant at each position in the area (area surrounded by a two-dot chain line in FIG. 3) of one segment SA and the boundary between two adjacent segments SA which are turned on should not be visible. Furthermore, it is desirable that, when one segment SA is turned on and another adjacent segment SA is turned off, a light leakage (halo effect) from the on-state segment SA to the off-state segment SA should not occur.

In the segment SA shown in FIG. 3, the number of light emitting elements 2 suitable for the area of the segment SA is selected, and the light emitting elements 2 are arranged so that light can be emitted uniformly. It is known that light spreads spherically. In this regard, four light emitting elements 2 are arranged so that the reduction of the amount of light at four corners of the square segment SA can be prevented.

### Example 2

Next, the illuminating device IL according to Example 2 of the present embodiment will be described. FIG. 6 is a plan view showing a part of the illuminating device IL according to Example 2. The wiring substrate 1, the light emitting elements 2 and an optical protrusion 3 of the illuminating device IL are illustrated in FIG. 6.

As shown in FIG. 6, the illuminating device IL of Example 2 is different from Example 1 in further comprising the optical protrusion 3 as a protrusion. The optical protrusion 3 delimits the segment areas SA. The optical protrusion 3 is configured to suppress a light leakage from one segment area SA to another adjacent segment area SA.

The optical protrusion 3 extends along the boundaries of the segment areas SA. For example, a part of the optical protrusion 3 is disposed between two adjacent segment areas SA. Since the segment areas SA are arranged in a matrix as described above, the optical protrusion 3 is disposed in a lattice shape along the boundaries of the segment areas SA.

In Example 2, the optical protrusion 3 has a plurality of first optical protrusions 31 as a plurality of first protrusions, and a plurality of second optical protrusions 32 as a plurality of second protrusions. The optical protrusion 3 is composed of the first optical protrusions 31 and the second optical protrusions 32 which are integrally formed with each other. The first optical protrusions 31 each extend continuously in the first direction X, and are arranged at intervals in the second direction Y. The second optical protrusions 32 each extend continuously in the second direction Y, intersect the first optical protrusions 31, and are arranged at intervals in the first direction X.

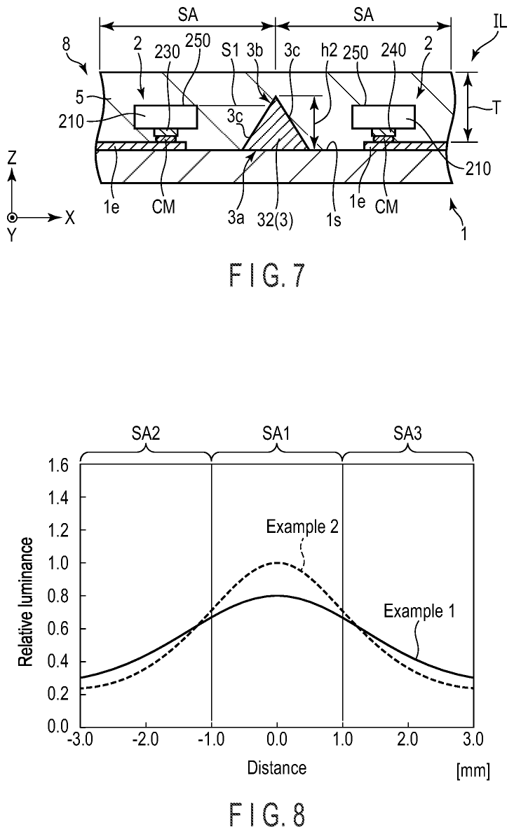

FIG. 7 is a cross-sectional view showing the illuminating device IL along line VII-VII of FIG. 6. The wiring substrate 1, the light emitting elements 2, the optical protrusion 3 and the protective layer 5 of the illuminating device IL are illustrated in FIG. 7.

As shown in FIG. 7, the optical protrusion 3 is in contact with the main surface 1s, is fixed to the main surface 1s, and protrudes toward above the wiring substrate 1. The optical protrusion 3 protrudes from the wiring substrate 1 toward the wavelength converter 9. The optical protrusion 3 is a solid member. The optical protrusion 3 is formed of a material coated by a printing method. Therefore, no adhesive material is interposed between the optical protrusion 3 and the main surface 1s.

In addition, by using a printing method, it is possible to dispose the optical protrusion 3 between the light emitting elements 2 even when the light emitting elements 2 which are mini-LEDs have a narrow pitch. The protective layer 5 is also disposed on the optical protrusion 3, and is in contact with the main surface 1s, the light emitting elements 2 and the optical protrusion 3. The wiring substrate 1, the light emitting elements 2, the optical protrusion 3 and the protective layer 5 constitute the light source 8 together with the above-described driver (4).

The outline of a cross section of the optical protrusion 3 in a plane (virtual plane) orthogonal to a direction in which the optical protrusion 3 extends has a contact line 3a and a protrusion line 3b. In the example of FIG. 6, the outline of a cross section of the second optical protrusion 32 in a plane orthogonal to a direction in which the second optical protrusion 32 extends has the contact line 3a and the protrusion line 3b. Although not shown in the drawing, the cross-sectional shape of the first optical protrusion 31 is the same as the cross-sectional shape of the second optical protrusion 32. The contact line 3a is in contact with the main surface 1s. The protrusion line 3b extends continuously from one end to the other end of the contact line 3a, and protrudes toward above the wiring substrate 1. The protrusion line 3b is composed of a plurality of line segments which are connected together with an angle.

In Example 2, the cross-sectional shape of the optical protrusion 3 (for example, the second optical protrusion 32) is a triangular shape, and one side constitutes the contact line 3a, and the remaining two sides constitute the protrusion line 3b. For example, the cross-sectional shape of the optical protrusion 3 is an isosceles triangular shape, and the optical protrusion 3 has a symmetry axis extending in the normal direction of the main surface 1s. The optical protrusion 3 has side surfaces 3c that are tilted from the main surface 1s.

The optical protrusion 3 is light reflective. The optical protrusion 3 is formed of, for example, a light reflective material dispersed in resin. The side surfaces 3c reflect light emitted from the light emitting elements 2 toward the wavelength converter 9. Accordingly, the optical protrusion 3 can reflect light heading from one segment area SA toward another adjacent segment area SA. For example, the optical protrusion 3 can reflect light above the one segment area SA.

In the present example, the surface 250 of the substrate 210 of the light emitting element 2 is a light emitting surface. However, the light emitting element 2 may be configured to emit light from a surface other than the surface 250. The optical protrusion 3 protrudes beyond a flush plane S1 which is flush with the surface 250. In Example 2, a height h2 of the optical protrusion 3 is 0.25 mm. Except for the above, the illuminating device IL of Example 2 is configured in the same manner as the illuminating device IL of Example 1.

Here, the inventors of the present invention simulated the optical properties of the illuminating device IL of each of Examples 1 and 2. FIG. 8 is a graph showing relative luminance in each of Examples 1 and 2. In FIG. 8, the center of a segment area SA1 is set as a reference position (0 mm), and the distance from the reference position to the right side is represented as a positive value and the distance from the reference position to the left side is represented as a negative value.

As shown in FIG. 8, during the simulation, only the light emitting elements 2 in the segment area SA1 located in a range of −1.0 mm to 1.0 mm were turned on, and the light emitting elements 2 in the remaining segment areas SA were turned off. For example, the light emitting elements 2 were turned off in a segment area SA2 located in a range of −3.0 mm to −1.0 mm and a segment area SA3 located in a range of 1.0 mm to 3.0 mm. The relative luminance in each of Examples 1 and 2 was normalized such that the maximum luminance in the segment area SA1 of Example 2 was 1.

It was found that the luminance level was maximum at the center of the segment area SA1 in both Examples 1 and 2. It was found that the luminance level of Example 2 was higher than the luminance level of Example 1 in the segment area SA1. It was found that the luminance level of Example 2 was closer to 0 than the luminance level of Example 1 in the segment areas SA other than the segment area SA1. In other words, the luminance level of Example 2 becomes higher than the luminance level of Example 1 in the segment area SA1 where it is desirable to increase the luminance level, and the luminance level of Example 2 becomes lower than the luminance level of Example 1 in the segment areas SA2 and SA3 where it is desirable to reduce the luminance level.

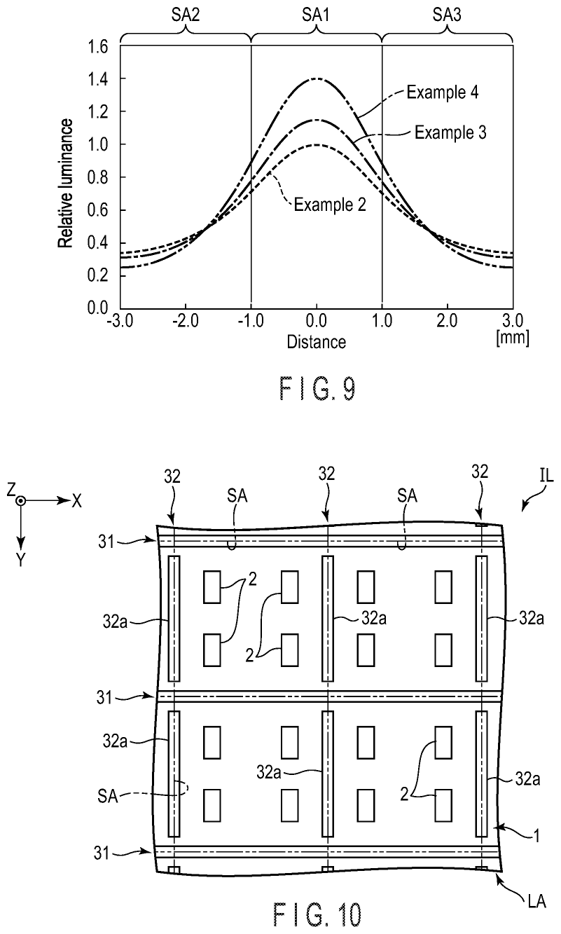

The inventors of the present invention further simulated the optical properties of the illuminating device IL of each of Examples 2, 3 and 4. FIG. 9 is a graph showing relative luminance in each of Examples 2, 3 and 4. In FIG. 9, the center of the segment area SA1 is set as a reference position (0 mm), and the distance from the reference position to the right side is represented as a positive value and the distance from the reference position to the left side is represented as a negative value.

As shown in FIG. 9, during the simulation, only the light emitting elements 2 in the segment area SA1 located in a range of −1.0 mm to 1.0 mm were turned on, and the light emitting elements 2 in the remaining segment areas SA were turned off. The relative luminance in each of Examples 2, 3 and 4 was normalized such that the maximum luminance in the segment area SA1 of Example 2 was 1. The illuminating device IL of Example 3 is configured in the same manner as the illuminating device IL of Example 2 except that the height h2 of the optical protrusion 3 is 0.30 mm. In addition, the illuminating device IL of Example 4 is configured in the same manner as the illuminating device IL of Example 2 except that the height h2 of the optical protrusion 3 is 0.35 mm.

It was found that the luminance level increases as the height h2 of the optical protrusion 3 increases in the segment area SA1. It was found that the luminance level approached 0 as the height h2 of the optical protrusion 3 increased in the segment areas SA (SA2 and SA3) other than the segment area SA1.

According to the display apparatus DSP of one embodiment configured as described above, the display apparatus DSP comprises the display panel PNL and the illuminating device IL. The illuminating device IL comprises the wiring substrate 1, the light emitting elements 2, the driver 4, the light diffuser 6 and the like. The light diffuser 6 can diffuse light emitted from the light emitting elements 2. Therefore, the occurrence of undesired variations in the luminance level in the light emitting area LA can be suppressed. In Examples 2 to 4, the illuminating device IL further comprises the optical protrusion 3. A halo effect becomes less likely to occur in the light emitting area LA, and therefore the reduction of the contrast ratio can be suppressed.

From the above, the illuminating device IL and the display apparatus DSP comprising the illuminating device IL capable of suppressing the occurrence of undesired variations in the luminance level in the light emitting area LA and suppressing the reduction of the contrast ratio can be obtained.

### Modification 1

Next, the illuminating device IL according to Modification 1 of the above embodiment will be described. FIG. 10 is a plan view showing the illuminating device IL according to Modification 1. The illuminating device IL of Modification 1 is different from the illuminating device IL of Example 2 in the configuration of the optical protrusion 3.

As shown in FIG. 10, the optical protrusion 3 has the first optical protrusions 31 and the second optical protrusions 32. The first optical protrusions 31 each extend continuously in the first direction X, and are arranged at intervals in the second direction Y. The second optical protrusions 32 each extend intermittently in the second direction Y, and are arranged at intervals in the first direction X. Each second optical protrusion 32 has a plurality of protrusion portions 32a arranged at intervals in the second direction Y. Each protrusion portion 32a is disposed between a pair of first optical protrusions 31 which are adjacent to each other in the second direction Y, and is spaced apart from the first optical protrusions 31.

As described above, the first optical protrusions 31 and the second optical protrusions 32 do not intersect each other. It is possible to avoid a situation where the intersections of the first optical protrusions 31 and the second optical protrusions 32 rise toward the light diffuser 6. For example, the increase of the thickness in the third direction Z of the illuminating device IL can be suppressed.

Unlike Modification 1, the first optical protrusions 31 may each extend continuously in the second direction Y, and the second optical protrusions 32 may each extend intermittently in the first direction X. Form the above, the optical protrusion 3 only needs to satisfy the following relationship.

The first optical protrusions 31 each extend continuously in one direction of the first direction X and the second direction Y, and are arranged at intervals in the other direction of the first direction X and the second direction Y. The second optical protrusions 32 each extend intermittently in the other direction, and are arranged at intervals in the one direction. Each second optical protrusion 32 has the protrusion portions 32a arranged at intervals in the other direction. Each protrusion portion 32a is disposed between a pair of first optical protrusions 31 which are adjacent to each other in the other direction, and is spaced apart from the first optical protrusions 31.

Also in the illuminating device IL of Modification 1 configured as described above, the first optical protrusions 31 and the second optical protrusions 32 can each reflect light heading from one segment area SA to another adjacent segment area SA. Therefore, the same effects as Example 2 can also be obtained in Modification 1.

### Modification 2

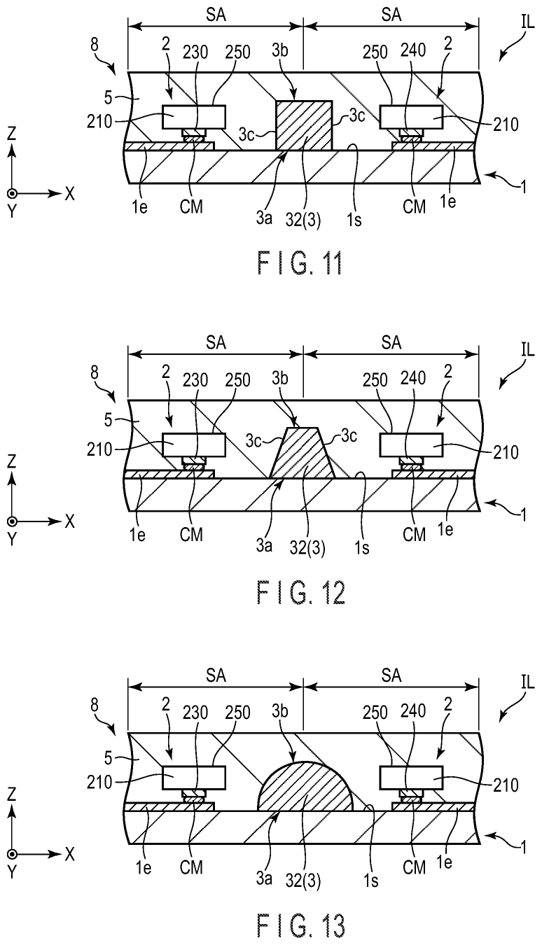

Next, the illuminating device IL according to Modification 2 of the above embodiment will be described. FIG. 11 is a cross-sectional view showing the illuminating device IL according to Modification 2. The illuminating device IL of Modification 2 is different from the illuminating device IL of Example 2 in the configuration of the optical protrusion 3. Although the second optical protrusion 32 is taken as an example here, the same applies to the first optical protrusion 31.

As shown in FIG. 11, the protrusion line 3b of the second optical protrusion 32 is composed of a plurality of line segments which are connected together with angles. In Modification 2, the cross-sectional shape of the second optical protrusion 32 is a rectangular shape, and one side of the rectangle constitutes the contact line 3a, and the remaining three sides of the rectangle constitute the protrusion line 3b. The side surfaces 3c are perpendicular to the main surface 1s.

### Modification 3

Next, the illuminating device IL according to Modification 3 of the above embodiment will be described. FIG. 12 is a cross-sectional view showing the illuminating device IL according to Modification 3. The illuminating device IL of Modification 3 is different from the illuminating device IL of Example 2 in the configuration of the optical protrusion 3. Although the second optical protrusion 32 is taken as an example here, the same applies to the first optical protrusion 31.

As shown in FIG. 12, the protrusion line 3b of the second optical protrusion 32 is composed of a plurality of line segments which are connected together with angles. In Modification 3, the cross-sectional shape of the second optical protrusion 32 is a trapezoidal shape. The lower base of the trapezoid constitutes the contact line 3a, and the upper base and the remaining two sides of the trapezoid constitute the protrusion line 3b. In the trapezoid of Modification 3, the upper base is shorter than the lower base, and the remaining two sides extend in a forward tapered shape. The side surfaces 3c are tilted from the main surface 1s.

### Modification 4

Next, the illuminating device IL according to Modification 4 of the above embodiment will be described. FIG. 13 is a cross-sectional view showing the illuminating device IL according to Modification 4. The illuminating device IL of Modification 4 is different from the illuminating device IL of Example 2 in the configuration of the optical protrusion 3. Although the second optical protrusion 32 is taken as an example here, the same applies to the first optical protrusion 31.

As shown in FIG. 13, the protrusion line 3b of the second optical protrusion 32 is composed of a curved line. In Modification 4, the cross-sectional shape of the second optical protrusion 32 is a semicircular shape, and the protrusion line 3b extends in an arc shape.

Also in the illuminating device IL of each of Modifications 2 to 4 configured as described above, the same effects as Example 2 can be obtained. When the protrusion line 3b is composed of a plurality of line segments, the cross-sectional shape of the optical protrusion 3 (for example, the second optical protrusion 32) may be another polygonal shape such as a square shape. Alternatively, when the protrusion line 3b is composed of a curved line, the cross-sectional shape of the optical protrusion 3 (for example, the second optical protrusion 32) may be a shape other than a semicircular shape such as a semielliptical shape.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Each of Examples 3 and 4 can be combined with any of the above modifications as needed.

For example, the optical protrusion 3 only needs to be configured to suppress a light leakage from one segment area SA to another adjacent segment area SA. Therefore, the optical protrusion 3 may not be light reflective but may be light diffusing or light shielding.

When the light diffusing optical protrusion 3 is used, the luminance level of one segment area SA can be increased by the optical properties of the optical protrusion 3, and the luminance level of another adjacent segment area SA can be prevented from being undesirably increased.

When the light shielding optical protrusion 3 is used, the optical protrusion 3 does not have an effect of increasing the luminance level of one segment area SA, but the optical protrusion 3 can prevent the luminance level of another adjacent segment area SA from being undesirably increased. Therefore, the illuminating device IL capable of suppressing the reduction of the contrast ratio can be obtained.

The height h2 of the optical protrusion 3 is not limited to the above examples but can be variously modified. For example, the optical protrusion 3 preferably protrudes beyond the flush plane S1 which is flush with the surface 250, but may not protrude beyond the flush plane S1 (FIG. 7).

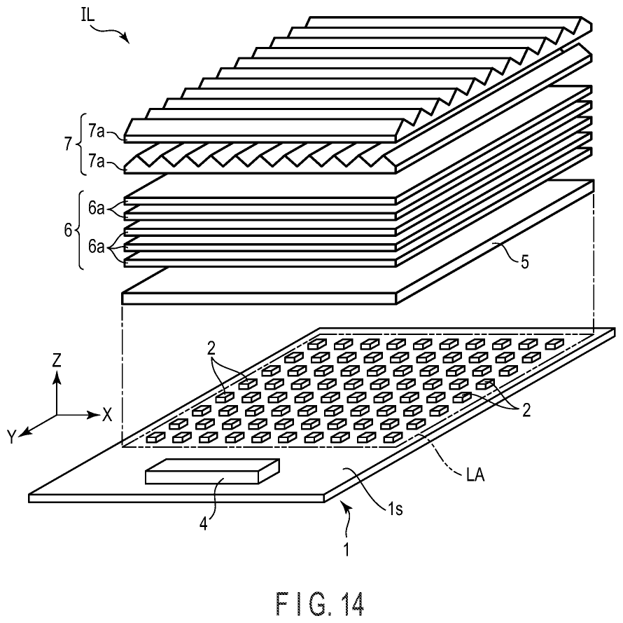

As shown in FIG. 14, the illuminating device IL may be formed without the wavelength converter 9. In that case, the protective layer 5 functions as a wavelength conversion element, and light emitted from the light emitting elements 2 is converted into a desired color phase by the protective layer 5 alone. The thickness of the illuminating device IL can be reduced by the wavelength converter 9.

The embodiment and modifications of the present invention are not limited to the illuminating device IL and the display apparatus DSP described above, but are also applicable to various illuminating devices and the display apparatus DSP comprising any of these illuminating devices.

What is claimed is:

1. An illuminating device comprising:
a wiring substrate;
a plurality of light emitting elements disposed on a main surface of the wiring substrate;
a wavelength conversion element irradiated with light emitted from the light emitting elements; and
a protrusion,
wherein
the main surface of the wiring substrate is divided into a plurality of segment areas,
n light emitting elements are disposed in each of the segment areas,
n is greater than 1,
the light emitting elements are driven independently in units of the segment areas, and
the protrusion protrudes from the wiring substrate toward the wavelength conversion element between two segment areas adjacent to each other.

2. The illuminating device of claim 1, wherein
the protrusion extends along boundaries of the segment areas and has a side surface intersecting the main surface, and
the side surface reflects the light emitted from the light emitting elements toward the wavelength conversion element.

3. The illuminating device of claim 1, wherein
the light emitting elements each have a base and a pad,
the base has a bottom surface opposed to the main surface and a top surface opposed to the bottom surface, and
the pad is sandwiched between the bottom surface and the wiring substrate, and is connected to the wiring substrate.

4. The illuminating device of claim 1, wherein
the light emitting elements each have a base,
the base has a bottom surface opposed to the main surface and a top surface opposed to the bottom surface, and
the protrusion protrudes beyond a plane flush with the top surface.

5. The illuminating device of claim 1, wherein
the segment areas are arranged in a matrix in a first direction and a second direction intersect each other, and
the protrusion is disposed in a lattice shape along boundaries of the segment areas.

6. The illuminating device of claim 5, wherein
the protrusion has
a plurality of first protrusions each extending continuously in the first direction and arranged at intervals in the second direction, and
a plurality of second protrusions each extending continuously in the second direction, intersecting the first protrusions, and arranged at intervals in the first direction.

7. The illuminating device of claim 5, wherein
the protrusion has
a plurality of first protrusions each extending continuously in one direction of the first direction and the second direction and are arranged at intervals in another direction of the first direction and the second direction, and
a plurality of second protrusions each extending intermittently in the other direction and arranged at intervals in the one direction,
each of the second protrusions has a plurality of protrusion portions arranged at intervals in the other direction, and
each of the protrusion portions is disposed between a pair of first protrusions adjacent to each other in the other direction, and is spaced apart from the first protrusions.

8. The illuminating device of claim 1, wherein
the light emitting elements are light-emitting diodes whose longest side length is less than or equal to 1 mm.

9. The illuminating device of claim 1, further comprising
a protective layer located between the main surface and the wavelength conversion element, disposed on the main surface, the light emitting elements and the protrusion, and protecting the light emitting elements,
wherein
the protective layer is configured as
a light transmissive layer which transmits a wavelength of the light emitted from the light emitting elements, or
a wavelength conversion layer which converts the wavelength of the light emitted from the light emitting elements, or
a photosynthesis layer where a plurality of phosphors absorbing the light emitted from the light emitting elements and emitting light having a different wavelength are dispersed in a light transmissive layer which transmits the wavelength of the light emitted from the light emitting elements.

10. The illuminating device of claim 1, further comprising:
a light diffuser located above the wavelength conversion element and configured to diffuse and emit the light emitted from the light emitting elements; and
a luminance improver located above the light diffuser and configured to focus and emit the light entering from the light diffuser.

11. A display apparatus comprising:
a display panel; and
an illuminating device illuminating the display panel,
wherein
the illuminating device comprises:
a wiring substrate;
a plurality of light emitting elements disposed on a main surface of the wiring substrate;
a wavelength conversion element irradiated with light emitted from the light emitting elements; and
a protrusion,
the main surface of the wiring substrate is divided into a plurality of segment areas,
n light emitting elements are disposed in each of the segment areas,
n is greater than 1,
the light emitting elements are driven independently in units of the segment areas, and
the protrusion protrudes from the wiring substrate toward the wavelength conversion element between two segment areas adjacent to each other.
